(19) United States
(12) Patent Application Publication
(10) Pub. No.: US 2026/0155340 A1
(43) Pub. Date: Jun. 4, 2026

(54) PLASMA PROCESSING APPARATUS AND PLASMA PROCESSING METHOD

(71) Applicant: Hitachi High-Tech Corporation, Minato-ku, Tokyo (JP)

(72) Inventors: Hitoshi TAMURA, Tokyo (JP); Hiroki MORI, Tokyo (JP); Mai ISOMOTO, Tokyo (JP)

(21) Appl. No.: 18/691,813

(22) PCT Filed: May 23, 2023
(86) PCT No.: PCT/JP2023/019040

§ 371 Date: Mar. 13, 2024

(51) Int. Cl. H01J 37/32

(52) U.S. Cl. CPC H01J 37/32669; H01J 37/32238; H01J 37/32678; H01J 2237/3345

(57) ABSTRACT

A processing chamber including a radio frequency power supply which supplies a microwave power, a dielectric plate disposed above the processing chamber and permeable by the microwave, an electromagnet disposed to surround the processing chamber and which generates a first static magnetic field, a static magnetic field generation device disposed below the processed substrate, and a control device which controls the electromagnet. The static magnetic field generation device generates a second static magnetic field in a direction to strengthen a static magnetic field included in the first static magnetic field and in parallel to a center axis of the processing chamber. The control device controls the electromagnet angle of a magnetic field line of a third static magnetic field with respect to the processed substrate. The third static magnetic field is a static magnetic field in which the first static magnetic field and the second static magnetic field are superimposed.

### TECHNICAL FIELD

The present disclosure relates to a plasma processing apparatus and a plasma processing method, and particularly relates to a plasma processing apparatus and a plasma processing method which apply a plasma processing to a processed substrate placed in a processing chamber while causing plasma to be generated in the processing chamber by using interaction between a microwave and a static magnetic field.

### BACKGROUND ART

Plasma processing apparatuses are used to produce semiconductor integrated circuit devices (hereinafter, may simply be referred to as semiconductor devices or devices) included in semiconductor integrated circuits. Die shrinks of the devices have been advanced for performance improvement and cost reduction of the devices. Conventionally, by a two-dimensional die shrink of the device, the number of devices which can be manufactured from one processed substrate (a semiconductor wafer, a semiconductor substrate, or may simply be referred to as a substrate) increases, and thus a manufacturing cost per device decreases, and also performance of the semiconductor integrated circuit can be improved by a size reduction effect, such as wiring length shortening. However, when a dimension of the semiconductor device becomes a nanometer order, which is close to a dimension of an atom, the two-dimensional die shrinking becomes significantly difficult. Therefore, measures such as application of a new material and a three-dimensional device structure are taken. These changes result in further increase in the manufacturing difficulty and increase in the number of manufacturing processes, and growth in manufacturing cost has been a serious problem.

Attachment of a fine particle or a pollutant to the semiconductor integrated circuit device in a process of manufacture leads to a fatal defect. Therefore, the semiconductor integrated circuit devices are manufactured in a clean room in which a particle and a pollutant are eliminated, and the temperature and humidity are optimally controlled. Along with the die shrinks of the devices, cleanliness of the clean room required for the manufacture becomes higher, and a huge cost is required for construction, and maintenance and operation of the clean room. Therefore, production by effectively utilizing the clean room space becomes necessary. From this point of view, size reduction and cost reduction of a semiconductor manufacturing apparatus is demanded.

In addition, within-wafer uniformity of plasma processing applied to the processed substrate is also important. In manufacturing of the semiconductor integrated circuit devices, in many cases, a disc-shaped silicon wafer having a diameter of 300 mm is used as a processed substrate. Multiple semiconductor integrated circuit devices are built on this silicon wafer. When the within-wafer uniformity of the plasma processing is poor, a smaller number of good-quality products (good-quality semiconductor chips) which satisfy product specifications can be acquired from one silicon wafer. Similarly, plasma processing stability in each processed substrate is also important. When quality of the plasma processing is unstable, and for example, the quality changes over time, the rate of good-quality products similarly decreases.

In a plasma processing apparatus which causes plasma to be generated by an electromagnetic wave, a plasma processing apparatus which utilizes, as the electromagnetic wave, a microwave whose frequency is at approximately several GHz, typically, 2.45 GHz, is widely used. Particularly, a plasma processing apparatus which utilizes electron cyclotron resonance (hereinafter, referred to as ECR) phenomenon caused by combination of a microwave and a static magnetic field exists. Such a plasma processing apparatus has excellent features that, for example, plasma can comparatively stably be generated even under a condition (for example, at an extremely low pressure) under which generation of plasma is normally difficult, and that plasma distribution can be controlled by static magnetic field distribution.

It is generally known that electrons which move in plasma applied with a static magnetic field receive force called Lorentz force, and diffusion of the electrons in a direction vertical to the static magnetic field is suppressed. Similarly, a phenomenon called ambipolar diffusion is known to be caused, in which ions in the plasma diffuse together by an electric field generated between the ions and electrons. Because of these effects, by making the static magnetic field act on the plasma, and suppressing diffusion in the direction vertical to the static magnetic field, density distribution of the plasma can be controlled.

In the plasma processing apparatus used for manufacturing of the semiconductor integrated circuit devices, in many cases, plasma called low-temperature plasma in which temperatures of electrons and ions are largely different is used. In the low-temperature plasma, it is said that the temperature of the electrons and the temperature of the ions are, although depending on a plasma generation condition, on the orders of several eV and 0.1 eV, respectively. Generally, densities of the electrons and ions are substantially equal to each other in the plasma, thus an electrically neutral state being maintained. However, at a vicinity of a plane where plasma contacts the processed substrate or a processing chamber, high-temperature and high-speed electrons escape to the wall, and a region called a sheath where remained ions become excessive is generated.

In the sheath, a strong electric field is locally caused by charge separation. Particularly, a sheath created at an interface of the processed substrate has large influence on the quality of the plasma processing. When radio frequency power is supplied to the processed substrate, direct-current bias voltage is caused in the processed substrate due to voltage-current characteristics of the sheath, and incident energy of the ions in the plasma to the surface of the processed substrate can be controlled. Optimization of this energy can improve, for example, in a case of plasma etching, quality of plasma processing, such as an etching speed and an etching shape. For example, in the plasma processing apparatus, a radio frequency (RF) power supply at a frequency of, for example, from 400 kHz to 13.56 MHz is electrically connected to the processed substrate to apply radio-frequency bias to the sheath. In many cases, an automatic matching device which corrects electric mismatching is used in the connection.

Theoretical treatment of the sheath has been described in many known documents. For example, NPL 1 describes that an incident speed of an ion to an interface between plasma and a sheath is at or higher than the Bohm velocity shown by Formula 1.

V_{Bohm}=√((eTₑ)/mᵢ) Formula 1

Here, V_{Bohm}: Bohm velocity (m/s), e: electric charge of electron (=1.602×10⁻¹⁹ C), mᵢ: mass of ion (kg), and Tₑ: temperature of electron (V).

That is, it is known that, at the sheath in contact with the processed substrate, ions are made incident to a sheath end at an initial speed at or higher than the Bohm velocity, and is accelerated by the electric field of the sheath to reach the processed substrate. The electric field of the sheath can be controlled by the radio-frequency bias, and the plasma processing quality can be improved.

In the plasma processing apparatus using the electron cyclotron resonance (ECR) described above, in many cases, a microwave is introduced parallelly to a static magnetic field from a strong static magnetic field region. Moreover, in many cases, the microwave is introduced in a form of a circularly polarized wave (hereinafter, be referred to as an R wave) in which an electric field rotates clockwise with respect to the static magnetic field. This is because it has theoretically been revealed that the R wave does not have cutoff in a strong magnetic field exceeding an ECR condition, and propagation is possible even in a high-density region. Here, the ECR condition indicates a static magnetic field where an electron cyclotron frequency matches a microwave frequency. When the microwave frequency is 2.45 GHz, the ECR condition corresponds to a static magnetic field of 875 gauss. That is, it is said that the R wave introduced into the strong magnetic field exceeding the ECR condition can propagate in the plasma even when high-density plasma occurs, and thus, the microwave power can be propagated to a region where the ECR is caused (a plane of electron cyclotron resonance (ECR): referred to as an ECR plane) so as to efficiently be absorbed. Moreover, a front surface of a processed surface of the processed substrate is, in many cases, placed substantially vertically to a static magnetic field in a weak magnetic field region to be opposed to an introduction surface of the microwave.

Generally, when the semiconductor integrated circuit device is manufactured by the plasma etching apparatus, a processing condition is adjusted to optimize processing quality of the etching processing corresponding to a film thickness and a type of a processed film. The processing condition includes a type and a flow rate of gas used for the etching processing, a pressure of a plasma processing chamber, an electric power for plasma generation, an RF bias power supplied to the processed substrate, and the like. Particularly, in an etching apparatus using an ECR plasma source, diffusion and a generating region of plasma are controllable by a static magnetic field, and static magnetic field distribution is an important parameter. In the ECR plasma, absorption of the microwave power to plasma strongly occurs locally at the ECR plane, and especially, a position of the ECR plane is important for control of the plasma generating region. It is considered that ions and chemically active radicals are actively generated at a vicinity of the ECR plane. By a distance between the ECR plane and the processed surface of the processed substrate being adjusted, ratios and densities of the ions and radicals on the processed surface of the processed substrate can be adjusted, and thus the plasma processing quality such as the processing shape can be optimized.

In the plasma etching processing, the flow rate and pressure of gas are also important parameters. By the RF bias being applied to the processed substrate, and the ions in plasma being drawn in, an etching speed at a surface of the processed substrate against which the ions collide (the processed surface of the processed substrate) increases, and thus anisotropy of the processing shape can be improved. At a low pressure, a frequency of collision between the ions and neutral gas molecules decreases, and rectilinearity of the ions increases. Therefore, in order to improve the processing shape anisotropy, etching processing at a low pressure is effective. Moreover, when the flow rate of gas is increased, a supply amount of active species necessary for etching reaction increases, and also reattachment of a reaction product to the surface of the processed substrate decreases, which is advantageous to acceleration of the etching speed. As described above, etching at a low pressure and with a large flow rate of gas is advantageous to the high-quality processing. However, reduction in the pressure and increase in the gas flow rate have a trade-off relation where balancing therebetween is difficult. Therefore, in the plasma etching apparatus, improving a vacuum exhaust capacity of the plasma etching apparatus is important.

FIG. 1 illustrates an etching apparatus 0100 as a comparative example of the plasma processing apparatus using the ECR. An electromagnet 0102 is provided around a plasma processing chamber 0107 in a substantially cylindrical shape, and a static magnetic field which causes the ECR can be applied inside the plasma processing chamber 0107. The electromagnet 0102 includes multi-stage solenoidal coils. A yoke 0110 is provided around an outer side of these solenoidal coils. By intensity of a magnetic field generated by each solenoidal coil being adjusted, static magnetic field distribution inside the processing chamber 0107 can be controlled. A microwave is supplied to a hollow part 0104 from a circular waveguide 0101 installed along a center axis of the plasma processing chamber 0107. The introduced microwave shapes electromagnetic field distribution at the hollow part 0104, and is introduced from the hollow part 0104 into the plasma processing chamber 0107 through a microwave introduction window 0105 and a shower plate 0106 disposed at a surface of the plasma processing chamber 0107. The surface is opposed to a front surface of a processed surface of a processed substrate 0103 disposed inside the plasma processing chamber 0107. A microwave at a frequency of 2.45 GHz is often used. Gas used for etching processing is supplied from a gas supply device (not illustrated) into the processing chamber 0107, through a fine gap (not illustrated) between the microwave introduction window 0105 and the shower plate 0106, and a plurality of fine gas supply holes (not illustrated) provided to the shower plate 0106. For the microwave introduction window 0105 and the shower plate 0106, quartz is often used as a material which is permeable by a microwave and is unlikely to adversely affect the plasma processing. Moreover, an inner surface of the plasma processing chamber 0107 is often protected by an inner cylinder made of quartz or the like to prevent damage from plasma. In this example, the substrate 0103 with a diameter of 300 mm is used as the processed substrate.

### CITATION LIST

### Non Patent Literature

NPL 1: Michael A. Lieberman and Allan J. Lichtenberg, Principles of plasma discharges and materials processing, Second Edition, Wiley-Interscience, First published 27 Jan. 2005, John Wiley & Sons, Inc.

### SUMMARY OF INVENTION

### Technical Problem

When etching was performed by using the plasma etching apparatus 0100 illustrated in FIG. 1, and shape evaluation was conducted, there was a case in which, depending on a processing condition, shape abnormality in which the shape became asymmetrical between an inner-side direction and an outer-side direction of the processed substrate 0103 was found at an outer circumferential part of the processed substrate 0103. The plasma etching shape is a complex phenomenon where various factors are combined, and thus identifying the cause is difficult. However, there is a possibility that reattachment of an etching reaction product generated from the processed substrate 0103 is the cause. That is, it might have been caused because density distribution of the reaction product on the processed substrate 0103 was uneven, and a larger amount reattached to one side.

The present disclosure provides a technique to prevent a defect of plasma processing at a vicinity of an outer circumferential part of a processed substrate. Other problems and new features will be revealed through description herein and the accompanying drawings.

### Solution to Problem

Outline of a representative one of the present disclosure can briefly be described as follows.

Provided herein according to one aspect of the present disclosure is a technique (a plasma processing apparatus or a plasma processing method) characterized by including:
a processing chamber in which a plasma processing is applied to a processed substrate;
a radio frequency power supply which supplies a microwave power through a waveguide;
a dielectric plate disposed above the processing chamber and permeable by the microwave;
a sample stage on which the processed substrate is placed;
an electromagnet disposed to surround a periphery of the processing chamber and which generates a first static magnetic field;
a static magnetic field generation device disposed below the processed substrate; and
a control device which controls the electromagnet, wherein
the static magnetic field generation device generates a second static magnetic field in a direction to strengthen a static magnetic field included in the first static magnetic field and in parallel to a center axis of the processing chamber,
the control device controls the electromagnet such that an angle of a magnetic field line of a third static magnetic field with respect to the processed surface of the processed substrate becomes a desired angle, and
the third static magnetic field is a static magnetic field in which the first static magnetic field and the second static magnetic field are superimposed one another.

### Advantageous Effects of Invention

According to the present disclosure, a defect of plasma processing at a vicinity of an outer circumferential part of a processed substrate can be prevented.

In more detail, a control device controls multi-stage electromagnets to control an angle of a static magnetic field caused by the multi-stage electromagnets and a static magnetic field generation device, with respect to a front surface of a processed surface of the processed substrate. Therefore, an incident angle of an ion which is made incident to the processed substrate can be controlled by etching processing using the plasma processing apparatus or the plasma processing method according to the present disclosure, and thus the aforementioned problem can be resolved. That is, the ion is made incident to a sheath end formed at the front surface of the processed surface of the processed substrate, along a magnetic field line. Therefore, an angle of the magnetic field line with respect to the front surface of the processed surface of the processed substrate at the vicinity of the outer circumferential part of the processed substrate can be controlled to be, for example, substantially vertical (substantially 90°). Hence, at the vicinity of the outer circumferential part of the processed substrate, the incident angle of the ion is controlled, and shape abnormality can be improved.

### BRIEF DESCRIPTION OF DRAWINGS

FIG. 1 is a schematic side sectional view of a microwave plasma etching apparatus according to a comparative example.

FIG. 2 is a schematic side sectional view of a microwave plasma etching apparatus according to one embodiment.

FIG. 3 is a schematic view of magnetic-field-line distribution of the microwave plasma etching apparatus according to the embodiment.

FIG. 4 is an explanatory diagram of a control device according to the embodiment.

FIG. 5 is a graph showing a magnetic-field-line angle of a processed substrate.

FIG. 6 is a graph showing an ECR height and a radius on the processed substrate.

FIG. 7 is a graph showing the magnetic-field-line angle on the processed substrate and the radius on the processed substrate.

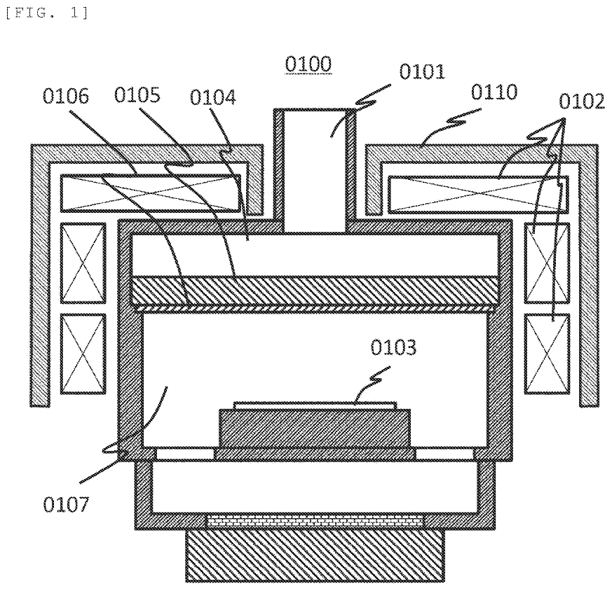

### DESCRIPTION OF EMBODIMENT

Hereinafter, one embodiment is described with reference to the drawings. In the following description, the same reference characters may be given to the same components to omit redundant description. Note that, in order to clarify the explanation, the drawings may be represented schematically when compared to an actual mode. However, the drawings are merely examples, and not intended to limit interpretation of the present invention.

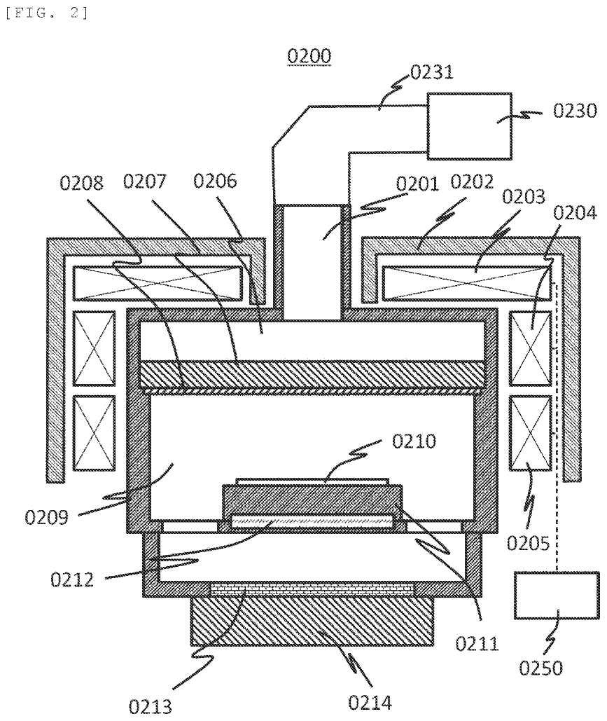

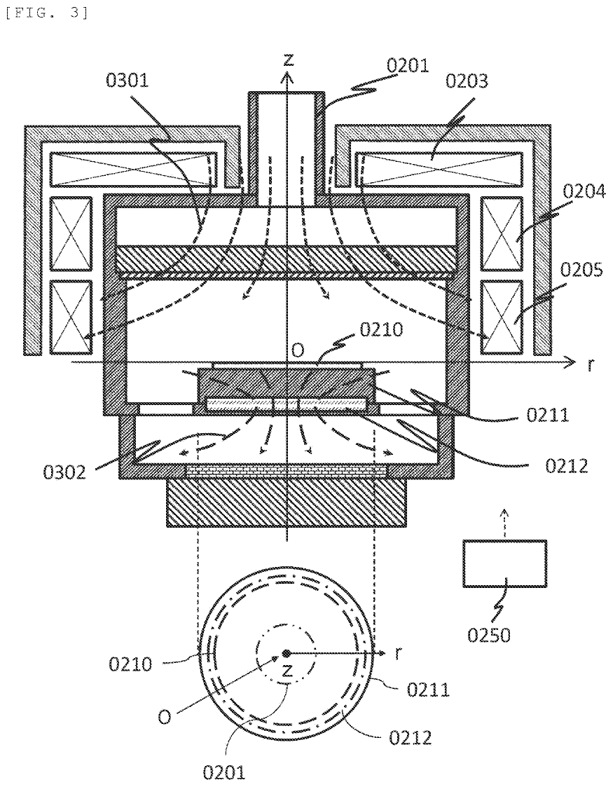

A microwave plasma etching apparatus according to one embodiment is described with reference to FIGS. 2 to 7. FIG. 2 is a schematic side sectional view (vertical sectional view) of the microwave plasma etching apparatus according to this embodiment. A processed substrate 0210 is, for example, a disc-shaped single-crystal silicon substrate with a diameter of 300 mm, and a semiconductor integrated circuit device is built on the processed substrate 0210. The microwave plasma etching apparatus (hereinafter, may simply be referred to as a plasma etching apparatus or a plasma processing apparatus) 0200 illustrated in FIG. 2 performs, by using plasma generated inside a substantially cylindrical processing chamber 0209, a plasma processing (here, etching processing) to a structure on a surface of the processed substrate 0210 placed on a substrate electrode 0211 as a sample stage. The structure is formed through another processing. The processed substrate 0210 has a disc shape when seen from above, and axially symmetrical plasma processing with respect to a center axis passing a center point of the disc-shaped processed substrate 0210 is required. Therefore, basically, the plasma etching apparatus 0200 also has an axially symmetrical structure with respect to the center axis when seen from above. Moreover, the substrate electrode 0211 has a circular shape when seen from above, and has an axially symmetrical shape with respect to the center axis. Here, the center point of the disc-shaped processed substrate 0210 corresponds to a center point O of the processed substrate 0210 illustrated in FIG. 3. The center axis passing the center point (0) of the processed substrate 0210 corresponds to a Z-axis as a center axis illustrated in FIG. 3. Being axially symmetrical with respect to the center axis means being axially symmetrical with respect to the Z-axis in FIG. 3. The axially symmetrical structure means an axially symmetrical structure with respect to the Z-axis in FIG. 3. The Z-axis as the center axis can be rephrased by a center axis of the plasma etching apparatus 0200, or a center axis of the processing chamber 0209. In this case, the center point (O) of the processed substrate 0210 and the center point of the substrate electrode 0211 are arranged on the center axis.

A microwave generated from a microwave source 0230 as a radio frequency power supply is propagated to a circular waveguide 0201 with a microwave propagation device 0231 interposed therebetween. The microwave propagation device 0231 includes an isolator, an automatic matching device, a rectangular waveguide, a circularly polarized wave generator, and the like. In other words, the microwave source 0230 supplies a microwave power to the circular waveguide 0201. The circular waveguide 0201 has a cylindrical shape and a circular tubular shape, and a center of the cylindrical shape is arranged on the center axis (Z-axis). That is, the center of the circular waveguide 0201 is arranged to be coaxial to the center axis of the processing chamber 0209. The microwave source 0230 supplies the microwave power to the processing chamber 0209 through the waveguide 0201.

The microwave circularly polarized by the circular waveguide 0201 is transmitted to a hollow part 0206 in a TE₁₁ mode which is a lowest order mode of the circular waveguide 0201. In this example, a microwave at a frequency of, for example, 2.45 GHz is used. Moreover, the circular waveguide 0201 with a diameter capable of propagating, for example, only the lowest order mode is used.

An electromagnetic field of the microwave is shaped at the hollow part 0206, and the shaped electromagnetic field is introduced into the processing chamber 0209 through a microwave introduction window 0207 and a shower plate 0208. The microwave introduction window 0207 and the shower plate 0208 are disposed above the processing chamber 0209, and can be deemed as a dielectric plate permeable by the microwave. The microwave introduction window 0207 can be deemed to be disposed at one of surfaces of the processing chamber 0209 intersecting with the center axis. As a material of the microwave introduction window 0207 and the shower plate 0208, a dielectric which is a material with small microwave loss, high plasma resistance, and no adverse effect on the plasma processing is desirably used. In this embodiment, quartz is used as the material of the microwave introduction window 0207 and the shower plate 0208. Gas which is supplied from a gas supplying device (not illustrated) and used for the etching processing is supplied into the processing chamber 0209 by a given amount, through a fine gap (not illustrated) between the microwave introduction window 0207 and the shower plate 0208, and a plurality of supply holes (not illustrated) provided to the shower plate 0208.

Around an outer side (around an outer circumference) of the cylindrically-shaped processing chamber 0209, upper, middle, and lower electromagnets 0203, 0204, and 0205 arranged in three stages are provided. The multi-stage electromagnets 0203, 0204, and 0205 can be deemed to be disposed coaxially to (or axially symmetrically with respect to) the center axis, while surrounding the periphery of the processing chamber 0209. Furthermore, a yoke 0202 is provided around an outer side of the electromagnets 0203, 0204, and 0205. The yoke 0202 is desirably made of a material with high permeability, and in this example, one made of iron is used. The electromagnets 0203, 0204, and 0205 are electrically connected to a control device 0250, and the control device 0250 can control drive current values of the electromagnets 0203, 0204, and 0205.

In this example, the first electromagnet 0203 as the upper-stage electromagnet is provided to surround a periphery of an upper part of the outer side of the processing chamber 0209, except for the installation position of the circular waveguide 0201. The second electromagnet 0204 as the middle-stage electromagnet is provided on a lower side of the first electromagnet 0203 so as to surround a periphery of an upper side-surface part of the outer side of the processing chamber 0209. In this example, the second electromagnet 0204 is provided around the upper side-surface part of the outer side of the processing chamber 0209 so as to surround a periphery of an outer side of the hollow part 0206 and the microwave introduction window 0207. The third electromagnet 0205 as the lower-stage electromagnet is provided on a lower side of the second electromagnet 0204 so as to surround a periphery of a middle side-surface part of the outer side of the processing chamber 0209. In this example, the third electromagnet 0205 is provided around the middle side-surface part of the outer side of the processing chamber 0209, between the shower plate 0208 and a static magnetic field generation device 0212 (described later).

In this embodiment, the three-stage electromagnets 0203, 0204, and 0205 are used as one example. However, the number of stages of the electromagnets may be multiple stages such as four or five stages, depending on need for fine adjustment of static magnetic field distribution. Alternatively, the number of stages of the electromagnets may be smaller such as two stages. In this embodiment, because of these electromagnets 0203, 0204, and 0205, a static magnetic field is strong in an upper side region or a region at the microwave introduction window 0207 side in the processing chamber 0209. A lower side region of the processing chamber 0209 (a region of the processing chamber 0209 corresponding to the lower side of the shower plate 0208, or a region of the processing chamber 0209 corresponding to an upper side of the substrate electrode 0211 which will be described later) is a divergent magnetic field where a static magnetic field is weak. The electromagnets 0203, 0204, and 0205 are configured to be axially symmetrical when seen from above (axially symmetrical with respect to the Z-axis), and the static magnetic field by the electromagnets 0203, 0204, and 0205 is also axially symmetrical when seen from above. By such a configuration, an ECR plane (a plane of electron cyclotron resonance (ECR)) at 875 gauss which is a condition for the electron cyclotron resonance (hereinafter, be referred to as the ECR) can be set inside the processing chamber 0209. By the control device 0250 adjusting the drive current values supplied to the electromagnets 0203, 0204, and 0205, a distance between the ECR plane and a processed surface of the processed substrate 0210 (may be referred to as an ECR height (h)) and a shape of the ECR plane can be controlled. Interaction between an introduced microwave and the static magnetic field can generate plasma inside the processing chamber 0209. Here, the electron cyclotron resonance can be deemed as electron cyclotron resonance caused by interaction of the microwave from the microwave source 0230, and the static magnetic field (may be referred to as a first static magnetic field) by the electromagnets 0203, 0204, and 0205.

The processed substrate 0210, and the substrate electrode 0211 with a placing surface to hold the processed substrate 0210 are provided inside the processing chamber 0209. The substrate electrode 0211 is provided inside the processing chamber 0209 to be opposed to the microwave introduction window 0207. On the placing surface of the substrate electrode 0211, the processed substrate 0210 whose center point is arranged coaxially to the center axis is placed.

The substrate electrode 0211 includes therein a mechanism to electrostatically attract and hold the processed substrate 0210, a mechanism to control temperature of the processed substrate 0210, and a mechanism to supply RF (Radio frequency) bias to the processed substrate 0210. The processing chamber 0209 is provided with a vacuum exhaust device 0214 with an exhaust speed adjusting mechanism 0213 interposed therebetween. The exhaust speed adjusting mechanism 0213, the vacuum exhaust device 0214, and a gas supply mechanism (not illustrated) allow given gas to be supplied to the processing chamber 0209 at a given pressure and at a given flow rate. The etching processing is also affected by flow of gas inside the processing chamber 0209, and thus, in order to make the gas flow axially symmetrical when seen from above, a structure (for example, arrangement positions of the plurality of supply holes provided to the shower plate 0208) is also made axially symmetrical.

The static magnetic field generation device 0212 is provided to a back surface side of the substrate electrode 0211 as a static magnetic field generation source, the back surface being opposed to the placing surface of the substrate electrode 0211. In this example, the static magnetic field generation device 0212 is built in the substrate electrode 0211. In other words, it can be said that, in the state in which the processed substrate 0210 is placed on the placing surface of the substrate electrode 0211, the static magnetic field generation device 0212 is disposed on a back surface side of the processed substrate 0210, with respect to the processed surface of the processed substrate 0210. Alternatively, in other words, it can be said that the static magnetic field generation device 0212 is disposed below the processed substrate 0210.

A static magnetic field on a front surface of the processed surface of the processed substrate 0210 is a static magnetic field (may be referred to as a third static magnetic field) where the first static magnetic field by the electromagnets 0203, 0204, and 0205, and a second static magnetic field by the static magnetic field generation device 0212 are superimposed (synthesized) one another. The static magnetic field generation device 0212 generates the second static magnetic field in a direction to strengthen the static magnetic field included in the first static magnetic field and in parallel to the center axis of the processing chamber 0209. By the static magnetic field generation device 0212, an angle of the static magnetic field (third static magnetic field) can be controlled to be vertical (90°) or substantially vertical (substantially 90°) with respect to the front surface of the processed surface of the processed substrate 0210. An electromagnet or a permanent magnet may be used as the magnetic field generation device 0212. In this embodiment, a configuration example in which a permanent magnet is used as the static magnetic field generation device 0212 is described. When an electromagnet is used as the static magnetic field generation device 0212, there is an advantage that a size and distribution of the static magnetic field can easily be controlled by adjustment of a drive current. However, in this case, a cooling mechanism, a current supply mechanism, and the like are required, which may be disadvantageous to size reduction of the static magnetic field generation device 0212. Moreover, the static magnetic field generation device 0212 is desirably disposed near the surface of the processed substrate 0210. When the static magnetic field generation device 0212 is disposed away from the surface of the processed substrate 0210, the static magnetic field generated by the static magnetic field generation device 0212 needs to be a strong static magnetic field. Therefore, the size reduction of the static magnetic field generation device 0212 becomes more difficult. Disposition of a large electromagnet in a vacuum discharging path leads to lowering of discharging performance, and thus, in this embodiment, the static magnetic field generation device 0212 using the permanent magnet which is capable of size reduction is disposed near the processed substrate 0210. In detail, the static magnetic field generation device 0212 using the permanent magnet is provided to the back surface side of the substrate electrode 0211, the back surface being opposed to the placing surface of the substrate electrode 0211 on which the processed substrate 0210 is placed. The static magnetic field generation device 0212 using the permanent magnet has a circular shape when seen from above. Similarly, the substrate electrode 0211 has a circular shape when seen from above.

FIG. 3 is a schematic view of magnetic-field-line distribution of the microwave plasma etching apparatus according to this embodiment. Moreover, FIG. 3 shows relation, when seen from above, between the positions of the circular waveguide 0201, the processed substrate 0210, the substrate electrode 0211, and the static magnetic field generation device 0212, the origin O (described later), the z-axis, and the r-axis. Note that although a short control line indicated by a broken arrow outputted from the control device 0250 is originally connected to the electromagnets 0203, 0204, and 0205 similarly to FIG. 2, it is indicated by the short control line for simplification of FIG. 3.

In FIG. 3, a magnetic field line (may be referred to as a first magnetic field line) 0301 generated only by the electromagnets 0203, 0204, and 0205, and a magnetic field line (may be referred to as a second magnetic field line) 0302 generated only by the static magnetic field generation device 0212 are schematically illustrated. Although, actually, the static magnetic fields generated by both of the magnetic field lines 0301 and 0302 are superimposed one another, in FIG. 3, each of the magnetic field lines 0301 and 0302 assuming that the other one does not exist is illustrated for convenience to explain the operation. In FIG. 3, the z-axis is indicated in a vertical direction and the r-axis is indicated in a radial direction, assuming that the center axis of the front surface of the processed surface of the disc-shaped processed substrate 0210 is the origin O. The magnetic field line 0301 by the electromagnets 0203, 0204, and 0205 is in a downward direction on the z-axis, and the magnetic field line 0302 by the static magnetic field generation device 0212 is also in the downward direction on the z-axis, thus generating the static magnetic fields in the direction strengthening one another. That is, the static magnetic field generation device 0212 generates the static magnetic field by the magnetic field line 0302, in the direction to strengthen the static magnetic field included in the static magnetic field by the magnetic field line 0301 generated by the multi-stage electromagnets 0203, 0204, and 0205, and in parallel to the center axis. Conversely, static magnetic fields both in the upward direction may be used. On the other hand, when an r-axis direction component is seen on the surface (on the r-axis) of the processed substrate 0210, the magnetic field line 0301 by the electromagnets 0203, 0204, and 0205 is in an outward direction, and the magnetic field line 0302 by the static magnetic field generation device 0212 is in an inward direction. Therefore, it can be seen that the r-direction components cancel out (weaken) each other by the superimposition of the respective magnetic field lines. That is, in the configuration illustrated in FIG. 3, the static magnetic field is adjusted to be more vertical with respect to the surface of the processed substrate 0210 by operation of the static magnetic field generation device 0212 near the surface of the processed substrate 0210. Although in FIG. 3 the case in which the electromagnets 0203, 0204, and 0205 are arranged in three stages is described, it is apparent that a similar effect to make the static magnetic field vertical can be achieved by a configuration with a different number of electromagnet stages. However, the number of adjustment parameters becomes smaller when the number of electromagnet stages is smaller, which may result in decrease in freedom of adjustment as will be described later. For the sake of adjustment of parameters such as the height of the ECR plane while making the static magnetic field vertical on the processed substrate 0210 (described later), the electromagnets (0203, 0204, 0205) of two or more stages are preferably provided.

As illustrated in FIG. 3, when seen from above, the centers of the circular waveguide 0201, the substrate electrode 0211, the processed substrate 0210, and the static magnetic field generation device 0212 are arranged coaxially to match the origin O as the center axis of the front surface of the processed surface of the disc-shaped processed substrate 0210, and the circular waveguide 0201, the substrate electrode 0211, the processed substrate 0210, and the static magnetic field generation device 0212 are arranged to make axial symmetry with respect to the z-axis passing the origin O. In terms of the sizes of the substrate electrode 0211, the processed substrate 0210, and the static magnetic field generation device 0212 when seen from above, in this example, the disc-shaped (or circular shaped) substrate electrode 0211 is the largest, the disc-shaped (or circular shaped) static magnetic field generation device 0212 using the permanent magnet is the second largest, and the disc-shaped (or circular shaped) processed substrate 0210 is the third largest. Therefore, an angle of the third static magnetic field, which is the synthesis of the first static magnetic field by the electromagnets 0203, 0204, and 0205, and the second static magnetic field by the static magnetic field generation device 0212, at an outer circumferential part of the processed surface of the processed substrate 0210 can be controlled to be vertical (90°) or substantially vertical (substantially 90°) with respect to the front surface of the processed surface of the processed substrate 0210.

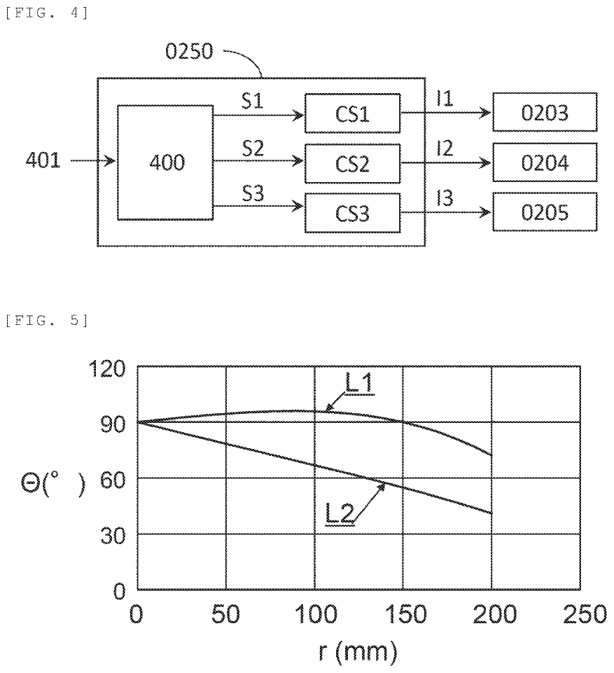

Operation of the control device 0250 which controls the electromagnets 0203, 0204, and 0205 is described with reference to FIG. 4. FIG. 4 is an explanatory diagram of the control device according to this embodiment. The reference numerals shown in FIGS. 2 and 3 are used as necessary for explanation. The control device 0250 includes a current control device 400, and a plurality of current sources CS1, CS2, and CS3. This example shows a case in which the plurality of current sources CS1, CS2, and CS3 includes the three current sources CS1, CS2, and CS3 corresponding to the three-stage electromagnets 0203, 0204, and 0205.

The current control device 400 has a function to calculate the drive currents of the electromagnets 0203, 0204, and 0205 which make the angle of the static magnetic field at the front surface of the processed surface of the processed substrate 0210 be vertical to the front surface of the processed surface, while satisfying an inputted static magnetic field specification 401. The current control device 400 receives input of the static magnetic field specification 401, calculates current control signals S1, S2, and S3 in accordance with the static magnetic field specification 401, and then sends the calculated current control signals S1, S2, and S3 to the current sources CS1, CS2, and CS3. The current sources CS1, CS2, and CS3 supply drive currents I1, I2, and I3 corresponding to the current control signals S1, S2, and S3 to the electromagnets 0203, 0204, and 0205, respectively. Hence, the current control device 400 can control the magnetic field line 0301 generated from the multi-stage electromagnets 0203, 0204, and 0205, and the static magnetic field based thereon. Although FIG. 4 shows the case of the three-stage electromagnets 0203, 0204, and 0205, the similar holds for a case with a different number of stages.

In this embodiment, the static magnetic field specification 401 is a static magnetic field specification defining, as a parameter, the distance (hereinafter, the ECR height (h)) between the ECR plane and the front surface of the processed surface of the processed substrate 0210 on the center axis (z-axis) of the microwave plasma etching apparatus 0200. This is because, as described above, the ECR plane is an important parameter to define the plasma processing characteristics. Although the static magnetic field specification 401 may include another item, or a plurality of items, the number of specification items which can be set is limited by the number of stages of the electromagnets (0203, 0204, 0205). For example, in a case of using a single-stage electromagnet, when the static magnetic field at the vicinity of the front surface of the processed surface of the processed substrate 0210 is controlled to be vertical to the front surface of the processed surface of the processed substrate 0210, the current value to be supplied to the electromagnet is uniquely defined, and there is no room for adjustment of the static magnetic field specification 401 such as the ECR height. In principle, one item of the static magnetic field specification 401 can be satisfied in maximum in the case of two-stage electromagnets, and two items of the static magnetic field specification 401 can be satisfied in maximum in the case of three-stage electromagnets. The similar holds for the case of electromagnets in four or more stages. Needless to say, for example, the number of items of the static magnetic field specification 401 for three-stage electromagnets may be made to one, so that redundancy is provided.

Generally, when a plurality of static magnetic field generation sources (0212) are provided, an overall static magnetic field is superimposition of static magnetic fields generated when the respective static magnetic field generation sources (0212) exist individually. A storage device in the current control device 400 stores, as reference data, a first distribution data of static magnetic flux density caused by the permanent magnet (0212) alone inside the processing chamber 0209, and a second distribution data of static magnetic flux density caused by the multi-stage electromagnets (0203, 0204, 0205) alone driven by a given current inside the processing chamber 0209. Static magnetic flux density at an arbitrary coordinate (r, z) inside the processing chamber 0209 can be obtained based on the following Formula 2 by linear superposition using the first distribution data and the second distribution data.

$$\begin{matrix}[ Math 1 ] & \\ \{ \begin{matrix}{B}_{r} ( r , z ) = {B}_{mr} ( r , z ) + {\sum }_{i = 1}^{3} {B}_{ir} ( r , z ) \frac{{I}_{i}}{{I}_{0 i}} \\ {B}_{z} ( r , z ) = {B}_{mz} ( r , z ) + {\sum }_{i = 1}^{3} {B}_{iz} ( r , z ) \frac{{I}_{i}}{{I}_{0 i}}\end{matrix} & ( Formula 2 )\end{matrix}$$

Bᵣ (r, z): an r-direction component of magnetic flux density at the coordinate (r, z) inside the processing chamber when I; (A) is supplied to all the electromagnets i (i=1, 2, and 3) (Here, the electromagnet 1, the electromagnet 2, and the electromagnet 3 correspond to the electromagnet 0203, the electromagnet 0204, and the electromagnet 0205, respectively.)

B_{z} (r, z): an z-direction component of the magnetic flux density at the coordinate (r, z) inside the processing chamber when Iᵢ (A) is supplied to all the electromagnets i (i=1, 2, and 3)

Bᵢᵣ(r,z): an r-direction component of magnetic flux density at the coordinate (r, z) inside the processing chamber when a given current I₀ᵢ (A) is supplied only to the electromagnets i (i=1, 2, and 3)

B_{iz}(r, z): a z-direction component of the magnetic flux density at the coordinate (r, z) inside the processing chamber when the given current I₀ᵢ (A) is supplied only to the electromagnets i (i=1, 2, and 3)

Bₘᵣ(r, z): an r-direction component of magnetic flux density at the coordinate (r, z) inside the processing chamber only by the permanent magnet

B_{mz}(r, z): a z-direction component of the magnetic flux density at the coordinate (r, z) inside the processing chamber only by the permanent magnet

In this embodiment, Bᵢᵣ, B_{iz} (i=1, 2, and 3), Bₘᵣ, and B_{mz} are obtained in advance by theoretical calculation in the finite element method. Alternatively, Bᵢᵣ, B_{iz} (i=1, 2, and 3), Bₘᵣ, and B_{mz} may be obtained using values actually measured by using a magnetic sensor, or through theoretical calculation, as necessary.

For example, in a case in which an r-component of magnetic flux density at a certain point (r₀, z₀) is controlled to be a specific value B₀ᵣ, as can be apparent from Formula 2, a linear function relation is established between the currents Iᵢ (i=1, 2, and 3). For example, when the currents I₁ and I₂ are supplied within an energizable range of the electromagnets 0203 and 0204, and the current I₃ is calculated, and the current I₃ is within an energizable range of the electromagnet 0205, the magnetic flux density distribution can further be calculated by using Formula 2. Based on the calculated magnetic flux density distribution, a combination of the currents I₁, I₂, and I₃ which satisfy the desired specification can be explored.

Although the case where the number of stages of the electromagnets is three is described above, the similar holds for the case with a different number of stages.

In this embodiment, it is desired that the angle of the magnetic field line on the front surface of the processed surface of the processed substrate 0210 is controlled to be vertical (or substantially vertical) with respect to the front surface of the processed surface of the processed substrate 0210. Furthermore, since the divergent magnetic field is used, the magnetic field line tends to deviate from the vertical direction more largely as separating from the center point O of the processed substrate 0210. Moreover, by the r-component of the magnetic flux density being made to zero, the angle of the magnetic field line can be made vertical to the front surface of the processed surface of the processed substrate 0210. Based on the above, the r-component of the magnetic flux density at the outermost circumferential position of the processed substrate 0210 is controlled to be zero.

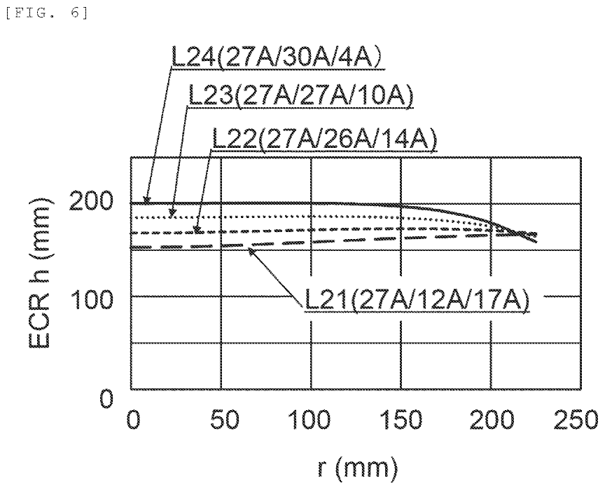

FIG. 5 is a graph showing the magnetic-field-line angle on the processed substrate. An example in which the magnetic-field-line angle on the processed substrate 0210 is controlled to be vertical is described with reference to FIG. 5. In the graph in FIG. 5, a vertical axis indicates an angle θ(°) of a magnetic flux density vector with respect to the surface of the processed substrate 0210 on the processed substrate 0210. A horizontal axis indicates a radius r (mm) on the processed substrate. In the graph, a case in which the permanent magnet is disposed as the static magnetic field generation device 0212 (with permanent magnet: indicated by a line L1), and a case in which the permanent magnet is not disposed (without permanent magnet: indicated by a line L2) are compared. By the permanent magnet, the magnetic field line is adjusted to be vertical (90°) at a position where the radius is 150 mm which is the outermost circumference of the processed substrate 0210 with the diameter of 300 mm. It can be seen that, by using the permanent magnet, the magnetic field lines are generally made perpendicular over the substantially entire surface (within a range where the radius r is from 0 mm to 150 mm) of the processed substrate 0210.

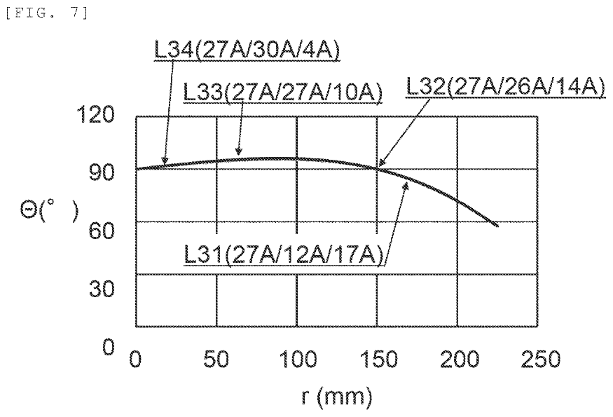

FIG. 6 is a graph showing the ECR height and the radius on the processed substrate. FIG. 7 is a graph showing the magnetic-field-line angle on the processed substrate and the radius on the processed substrate. In FIGS. 6 and 7, results of cases in which the ECR height (h (mm)) is controlled to be 150 mm, 170 mm, 185 mm, and 200 mm are illustrated. FIG. 6 shows the ECR height (h (mm)) at each radius (r (mm)), and FIG. 7 shows the magnetic-field-line angle θ(°) on the processed substrate 0210. In FIG. 7, since graphs with different current values overlap with each other, one line is shown.

In FIG. 6, a line L21 presents the case in which the ECR height (h (mm)) is adjusted to be 150 mm, and the drive current values (ampere: A) of the electromagnets 0203, 0204, and 0205 are 27 A, 12 A, and 17 A. A line L22 presents the case in which the ECR height (h (mm)) is adjusted to be 170 mm, and the drive current values (A) of the electromagnets 0203, 0204, and 0205 are 27 A, 26 A, and 14 A. A line L23 presents the case in which the ECR height (h (mm)) is adjusted to be 185 mm, and the drive current values (A) of the electromagnets 0203, 0204, and 0205 are 27 A, 26 A, and 10 A. A line L24 presents the case in which the ECR height (h (mm)) is adjusted to be 200 mm, and the drive current values of the electromagnets 0203, 0204, and 0205 are 27 A, 30 A, and 4 A.

In FIG. 7, a line L31 presents, similarly to the line L21, the case in which the ECR height (h (mm)) is adjusted to be 150 mm, and the drive current values (A) of the electromagnets 0203, 0204, and 0205 are 27 A, 12 A, and 17 A. A line L32 presents, similarly to the line L22, the case in which the ECR height (h (mm)) is adjusted to be 170 mm, and the drive current values (A) of the electromagnets 0203, 0204, and 0205 are 27 A, 26 A, and 14 A. A line L33 presents, similarly to the line L23, the case in which the ECR height (h (mm)) is adjusted to be 185 mm, and the drive current values (A) of the electromagnets 0203, 0204, and 0205 are 27 A, 26 A, and 10 A. A line L34 presents, similarly to the line L24, the case in which the ECR height (h (mm)) is adjusted to be 200 mm, and the drive current values (A) of the electromagnets 0203, 0204, and 0205 are 27 A, 30 A, and 4 A.

Therefore, as is apparent from FIGS. 6 and 7, in the case in which the diameter of the processed substrate 0210 is 300 mm, the ECR height h can be adjusted to a desired height from 150 mm to 200 mm while the angle θ(°) of the magnetic field line is made substantially vertical (90°) at a position where the radius r of the processed substrate 0210 is within a range from 0 mm to 150 mm. The diameter of the processed substrate 0210 is not limited to 300 mm, but may be smaller than 300 mm, or larger than 300 mm.

In this manner, a defect in the plasma processing at the vicinity of the outer circumferential part of the processed substrate 0210 can be prevented. That is, a plasma processing shape at the vicinity of the center of the processed substrate 0210 and a plasma processing shape at the vicinity of the outer circumferential part of the processed substrate 0210 can be made same as each other. Furthermore, a plasma processing shape can be made same from the vicinity of the center of the processed substrate 0210 to the vicinity of the outer circumferential part of the processed substrate 0210. Therefore, quality of the plasma processing can be homogenized over the entire processed surface of the processed substrate 0210.

Moreover, since the distance between the ECR plane and the processed surface of the processed substrate can be adjusted, ratios and densities of ions and radicals on the processed surface of the processed substrate 0210 can be adjusted, and thus optimization of the quality of the plasma processing, such as the plasma processing shape, becomes possible.

Here, as described in the following (A) to (C), the current control device 400 controls the drive current values I1, I2, and I3 supplied to the multi-stage electromagnets 0203, 0204, and 0205.
(A) The current control device 400 controls the drive current values I1, I2, and I3 supplied to the multi-stage electromagnets 0203, 0204, and 0205, so as to control the angle, with respect to the front surface of the processed surface of the processed substrate, of the static magnetic field (third static magnetic field) based on the magnetic field line, which is the synthesis (superimposition) of the static magnetic field (first static magnetic field) based on the magnetic field line 0301 by the multi-stage electromagnets 0203, 0204, and 0205, and the static magnetic field (second static magnetic field) based on the magnetic field line 0302 by the static magnetic field generation device 0212. In other words, the current control device 400 is configured to be able to control the electromagnet (0203, 0204, 0205) such that the angle of the magnetic field line of the third static magnetic field with respect to the processed surface of the processed substrate 0210 becomes a desired angle.
(B) Moreover, the current control device 400 controls the drive current values of the multi-stage electromagnets 0203, 0204, and 0205 such that 1) the angle of the third static magnetic field with respect to the front surface of the processed surface becomes substantially vertical (substantially 90°) at the outer circumferential part of the processed surface of the processed substrate 0210, and 2) the height between the ECR plane and the front surface of the processed surface of the processed substrate 0210 becomes a desired height.
(C) Moreover, the current control device 400 controls the drive current values of the multi-stage electromagnets 0203, 0204, and 0205 such that the angle of the third static magnetic field with respect to the front surface of the processed surface becomes substantially vertical (substantially 90°) over the entire processed surface of the processed substrate 0210.

A plasma processing method using the plasma etching apparatus 0200 according to this embodiment includes the following processes of Steps S1, S2, and S3.
(Step S1) A substrate loading process in which the processed substrate 0210 is placed on the placing surface of the substrate electrode 0211 inside the processing chamber 0209.
(Step S2) A plasma generating process in which plasma is generated inside the processing chamber 0209.
(Step S3) A plasma processing process in which gas is supplied into the processing chamber 0209 to conduct the plasma processing.
(Step S4) A substrate unloading process in which, after completion the plasma processing process, the processed substrate 0210 is unloaded outside the processing chamber 0209.

At Step S2, the multi-stage electromagnets 0203, 0204, and 0205 are controlled by the current control device 400 to generate the first static magnetic field based on the first magnetic field line 0301.

At this Step S2, as described earlier in (A) to (C), the current control device 400 controls the drive current values I1, I2, and I3 supplied to the multi-stage electromagnets 0203, 0204, and 0205. That is, Step S2 includes a first process to control the multi-stage electromagnets 0203, 0204, and 0205 such that the angle of the magnetic field line of the third static magnetic field with respect to the processed surface of the processed substrate 0210 becomes a desired angle. Furthermore, Step S2 includes a second process to control the multi-stage electromagnets 0203, 0204, and 0205 such that the height from the processed surface of the processed substrate 0210 to the plane of the electron cyclotron resonance becomes a desired height. Here, the first process is a process to control the multi-stage electromagnets 0203, 0204, and 0205 such that the angle of the magnetic field line of the third static magnetic field with respect to the outer circumferential part of the processed surface of the processed substrate 0210 becomes substantially 90°. Moreover, the first process is a process to control the multi-stage electromagnets 0203, 0204, and 0205 such that the angle of the magnetic field line of the third static magnetic field becomes substantially 90° over the entire processed surface of the processed substrate 0210. Note that the plasma generating process (Step S2) and the plasma processing process (Step S3) may be defined as a single process.

As a result, an incident angle of an ion which is made incident to the processed substrate 0210 can be controlled by the etching processing using the plasma processing apparatus 0200 or the plasma processing method according to the present disclosure, and thus the aforementioned problem can be resolved. The ion is made incident to a sheath end formed at the front surface of the processed surface of the processed substrate 0210, along the magnetic field line. Therefore, the angle of the magnetic field line with respect to the front surface of the processed surface of the processed substrate 0210 at the vicinity of the outer circumferential part of the processed substrate 0210 can be controlled to be, for example, substantially 90°. Hence, at the vicinity of the outer circumferential part of the processed substrate 0210, the incident angle of the iron is controlled and shape abnormality in the plasma processing is improved, and thus quality of the plasma processing, such as the plasma processing shape, can be improved.

Although the case in which the magnetic field line on the processed substrate 0201 is controlled to be vertical with respect to the processed substrate surface is described above, the magnetic field line may be similarly controlled to be a given angle. That is, as the static magnetic field specification, in addition to the ECR height, the magnetic-field-line angle with respect to the processed substrate surface may be added. Regarding the asymmetric shape at the outer circumferential part of the processed substrate which is seen in the plasma etching apparatus of the comparative example, the processing shape can be improved by the control of the ion incident angle.

Although the disclosure by the present disclosing party is describe above in detail based on the embodiment, the present disclosure is not limited to the embodiment, and needless to say, various changes are applicable.

### REFERENCE SIGNS LIST

0101: circular waveguide
0102: electromagnet
0103: processed substrate
0104: hollow part
0105: microwave introduction window
0106: shower plate
0107: plasma processing chamber
0201: circular waveguide
0202: yoke
0203: electromagnet
0204: electromagnet
0205: electromagnet
0206: hollow part
0207: microwave introduction window
0208: shower plate
0209: processing chamber
0210: processed substrate
0211: substrate electrode
0212: static magnetic field generation device
0213: exhaust speed adjusting mechanism
0214: vacuum exhaust device
0250: control device
0301: magnetic field line (first magnetic field line)
0302: magnetic field line (second magnetic field line)
400: current control device
401: static magnetic field specification

1. A plasma processing apparatus, characterized by comprising:
a processing chamber in which a plasma processing is applied to a processed substrate;
a radio frequency power supply configured to supply a microwave power through a waveguide;
a dielectric plate disposed above the processing chamber and permeable by the microwave;
a sample stage on which the processed substrate is placed;
an electromagnet disposed to surround a periphery of the processing chamber and configured to generate a first static magnetic field;
a static magnetic field generation device disposed below the processed substrate; and
a control device configured to control the electromagnet, wherein
the static magnetic field generation device generates a second static magnetic field in a direction to strengthen a static magnetic field included in the first static magnetic field and in parallel to a center axis of the processing chamber,
the control device controls the electromagnet such that an angle of a magnetic field line of a third static magnetic field with respect to a processed surface of the processed substrate becomes a desired angle, and
the third static magnetic field is a static magnetic field in which the first static magnetic field and the second static magnetic field are superimposed one another.

2. The plasma processing apparatus according to claim 1, characterized in that the static magnetic field generation device is a permanent magnet.

3. The plasma processing apparatus according to claim 2, characterized in that the desired angle is substantially 90°.

4. The plasma processing apparatus according to claim 2, characterized in that the control device controls the electromagnet such that:
the angle becomes substantially 90° at an outer circumferential part of the processed surface; and
a height from the processed surface to a plane of electron cyclotron resonance becomes a desired height, and
the electron cyclotron resonance is electron cyclotron resonance caused by interaction of the microwave and the first static magnetic field.

5. The plasma processing apparatus according to claim 4, characterized in that the control device controls the electromagnet such that the angle becomes substantially 90° over the entire processed surface.

6. A plasma processing method using a plasma processing apparatus including:
a processing chamber in which a plasma processing is applied to a processed substrate;
a radio frequency power supply configured to supply a microwave power through a waveguide;
a dielectric plate disposed above the processing chamber and permeable by the microwave;
a sample stage on which the processed substrate is placed;
an electromagnet disposed to surround a periphery of the processing chamber and configured to generate a first static magnetic field; and
a static magnetic field generation device configured to generate a second static magnetic field in a direction to strengthen a static magnetic field included in the first static magnetic field and in parallel to a center axis of the processing chamber, and disposed below the processed substrate,
the plasma processing method characterized by comprising the step of a first process to control the electromagnet such that an angle of a magnetic field line of a third static magnetic field with respect to a processed surface of the processed substrate becomes a desired angle, wherein
the third static magnetic field is a static magnetic field in which the first static magnetic field and the second static magnetic field are superimposed one another.

7. The plasma processing method according to claim 6, characterized in that the desired angle is substantially 90°.

8. The plasma processing method according to claim 6, characterized by further comprising the step of a second process to control the electromagnet such that a height from the processed surface to a plane of electron cyclotron resonance becomes a desired height, wherein
the first process includes a process to control the electromagnet such that the angel becomes substantially 90° at an outer circumferential part of the processed surface, and
the electron cyclotron resonance is electron cyclotron resonance caused by interaction of the microwave and the first static magnetic field.

9. The plasma processing method according to claim 8, characterized in that the first process includes a process to control the electromagnet such that the angle becomes substantially 90° over the entire processed surface.
